(19) United States
(12) Patent Application Publication
(10) Pub. No.: US 2014/0091320 A1
(43) Pub. Date: Apr. 3, 2014

(54) SEMICONDUCTOR DEVICE AND METHOD FOR MANUFACTURING A SEMICONDUCTOR DEVICE

(71) Applicants: FUJITSU SEMICONDUCTOR LIMITED, Yokohama-shi (JP); FUJITSU LIMITED, Kawasaki-shi (JP)

(72) Inventors: NORIKAZU NAKAMURA, Sagamihara (JP); Atsushi Yamada, Isehara (JP); Tetsuro Ishiguro, Kawasaki (JP); JUNJI KOTANI, Isehara (JP); Kenji Imanishi, Atsugi (JP)

(73) Assignees: FUJITSU SEMICONDUCTOR LIMITED, Yokohama-shi (JP); FUJITSU LIMITED, Kawasaki-shi (JP)

(21) Appl. No.: 13/968,843

(22) Filed: Aug. 16, 2013

(30) Foreign Application Priority Data
Sep. 28, 2012 (JP) 2012-218247

(51) Int. Cl. H01L 29/205

(52) U.S. Cl. CPC H01L 29/205
USPC 257/76; 438/172

(57) ABSTRACT

A semiconductor device includes a first semiconductor layer formed on a substrate, a second semiconductor layer formed on the first semiconductor layer, a third semiconductor layer and a fourth semiconductor layer formed on the second semiconductor layer, a gate electrode formed on the third semiconductor layer, and a source electrode and a drain electrode contacting and formed on the fourth semiconductor layer, wherein the third semiconductor layer is formed of a semiconductor material for attaining p-type on an area just under the gate electrode, and a concentration of silicon in the fourth semiconductor layer is higher than that in the second semiconductor layer.

### CROSS-REFERENCE TO RELATED APPLICATIONS

This application claims the benefit of priority based upon Japanese Patent Application No. 2012-218247 filed on Sep. 28, 2012, the entire contents of which are herein incorporated by reference.

### FIELD

A certain aspect of the embodiments discussed herein relates to a semiconductor device and a method for manufacturing a semiconductor device.

### BACKGROUND

GaN, AlN, or InN that is a nitride semiconductor, a material composed of a mixed crystal thereof, or the like has a higher saturated electron velocity or a wider band gap and is being studied for a higher withstand voltage or higher output electronic device. For a higher withstand voltage or higher output electronic device, a technique for a field-effect transistor (FET), in particular, a high electron mobility transistor (HEMT) is developed.

For an HEMT using a nitride semiconductor, a structure is provided in such a manner that an electron running layer is formed of GaN and an electron supplying layer is formed of AlGaN. In the HEMT with such a structure, a higher concentration of 2-dimensional electron gas (2DEG) is produced by a distortion caused by a difference between lattice constants of GaN and AlGaN, namely, a piezoelectric polarization, so that it is possible to obtain a semiconductor device with a higher efficiency and a higher output.

Meanwhile, a higher concentration of 2DEG is produced in the HEMT with a structure provided in such a manner that an electron running layer is formed of GaN and an electron supplying layer is formed of AlGaN, so as to have a problem that it is difficult to attain normally-off-state. Accordingly, in order to solve such a problem, a method is disclosed for forming a p-GaN layer between a gate electrode and an electron supplying layer to suppress production of a 2DEG just under the gate electrode and thereby provide a normally-off-state (for example, Japanese Patent Application Publication No. 2007-19309).

Meanwhile, a p-GaN layer formed between an electron supplying layer and a gate electrode is generally formed by forming a p-GaN layer on an entire surface of the electron supplying layer and subsequently removing the p-GaN layer in an area except an area where the gate electrode is to be formed, by dry etching. However, an in-plane distribution of etching is produced in dry etching, and hence, when a p-GaN layer is removed entirely, a part of an electron supplying layer may also be removed. Thus, when a part of an electron supplying layer is removed to provide a thinner electron supplying layer, a density of a 2DEG may be lowered so that an on-resistance may be higher. Additionally, such dry etching is conducted by, for example, reactive ion etching (RIE) using a gas that includes a chlorine component or the like.

Hence, a normally-off type semiconductor device with a lower on-resistance and a method for manufacturing such a semiconductor device are desired.

### SUMMARY

According to an aspect of the embodiments, a semiconductor device includes a first semiconductor layer formed on a substrate, a second semiconductor layer formed on the first semiconductor layer, a third semiconductor layer and a fourth semiconductor layer formed on the second semiconductor layer, a gate electrode formed on the third semiconductor layer, and a source electrode and a drain electrode contacting and formed on the fourth semiconductor layer, wherein the third semiconductor layer is formed of a semiconductor material for attaining p-type on an area just under the gate electrode, and a concentration of silicon in the fourth semiconductor layer is higher than that in the second semiconductor layer.

The object and advantages of the invention will be realized and attained by means of the elements and combinations particularly pointed out in the claims. It is to be understood that both the forgoing general description and the following detailed description are exemplary and explanatory and are not restrictive of the invention.

### BRIEF DESCRIPTION OF THE DRAWING(S)

FIG. 1 is a structural diagram of a semiconductor device in a first embodiment;

FIG. 2A and FIG. 2B are manufacturing process diagrams (1) of a semiconductor device in the first embodiment;

FIG. 3A and FIG. 3B are manufacturing process diagrams (2) of a semiconductor device in the first embodiment;

FIG. 4 is a structural diagram (1) of a sample fabricated to illustrate a characteristic of a semiconductor device;

FIG. 5 is a concentration distribution diagram obtained by SIMS for a nitride semiconductor layer of a semiconductor device in the first embodiment;

FIG. 6 is a structural diagram (2) of a sample fabricated to illustrate a characteristic of a semiconductor device;

FIG. 7 is a concentration distribution diagram obtained by SIMS for a nitride semiconductor layer that is not doped with silicon;

FIG. 8 is a structural diagram of a semiconductor device in a second embodiment;

FIG. 9 is an illustration diagram of a discretely packaged semiconductor device in a third embodiment;

FIG. 10 is a circuit diagram of an power supply device in the third embodiment; and

FIG. 11 is a structural diagram of a high power amplifier in the third embodiment.

### DESCRIPTION OF EMBODIMENT(S)

Embodiments for implementing the invention will be described below. Additionally, an identical numeral reference will be provided to an identical member or the like and descriptions thereof will be omitted.

### First Embodiment

(Semiconductor Device)

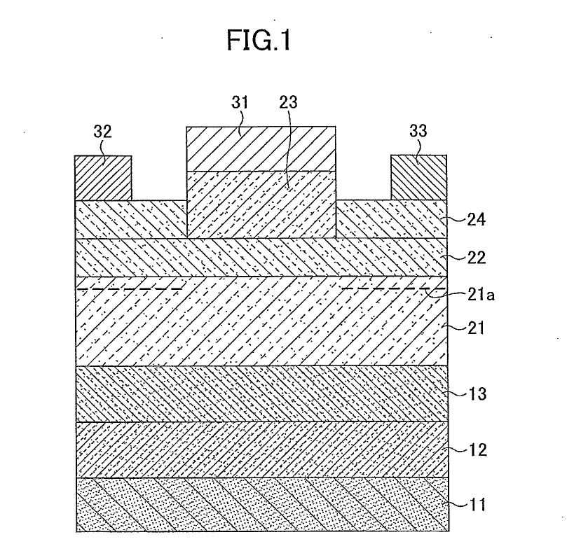

A semiconductor device in a first embodiment will be described. A semiconductor device in the present embodiment is an HEMT with a structure illustrated in FIG. 1.

Specifically, a nucleating layer 12, a buffer layer 13, an electron running layer 21, and an electron supplying layer 22 are formed on a substrate 11 composed of a semiconductor or the like. Thereby, 2DEG 21a is generated in the electron running layer 21 near an interface between the electron running layer 21 and the electron supplying layer 22. Furthermore, a p-GaN layer 23 is formed in an area where a gate electrode 31 is to be formed, on the electron supplying layer 22 and a regrowth electron supplying layer 24 is formed in an area except an area where the gate electrode 31 is to be formed. Furthermore, a source electrode 32 and a drain electrode 33 are formed on the regrowth electron supplying layer 24, and the gate electrode 31 is formed on the p-GaN layer 23. Additionally, the electron running layer 21, the electron supplying layer 22, the p-GaN layer 23, and the regrowth electron supplying layer 24 may be described as a first semiconductor layer, a second semiconductor layer, a third semiconductor layer, and a fourth semiconductor layer, respectively, in the present embodiment.

While a silicon substrate is used for the substrate 11 and the electron running layer 21 is formed of a GaN layer, the electron supplying layer 22 is formed of an AlGaN layer and the regrowth electron supplying layer 24 is formed of an AlGaN layer. Additionally, in the present embodiment, the regrowth electron supplying layer 24 is doped with silicon more than that of the electron supplying layer 22, as will be described below.

Because a semiconductor device in the present embodiment is such that the electron supplying layer 22 is formed thinly and further the p-GaN layer 23 is formed in an area where the gate electrode 31 is to be formed, it is possible to eliminate 2DEG 21a just under the gate electrode 31. Thereby, it is possible to provide a normally-off-state. Furthermore, the regrowth electron supplying layer 24 is formed on the electron supplying layer 22 in an area except an area where the gate electrode 31 is to be formed, so that the electron supplying layer is substantially thickly formed. Hence, it is possible to increase a density of 2DEG 21a in an area except just under the gate electrode 31, and thereby, it is possible to decrease an on-resistance.

(Method for Manufacturing a Semiconductor Device)

Next, a method for manufacturing a semiconductor device in the present embodiment will be described.

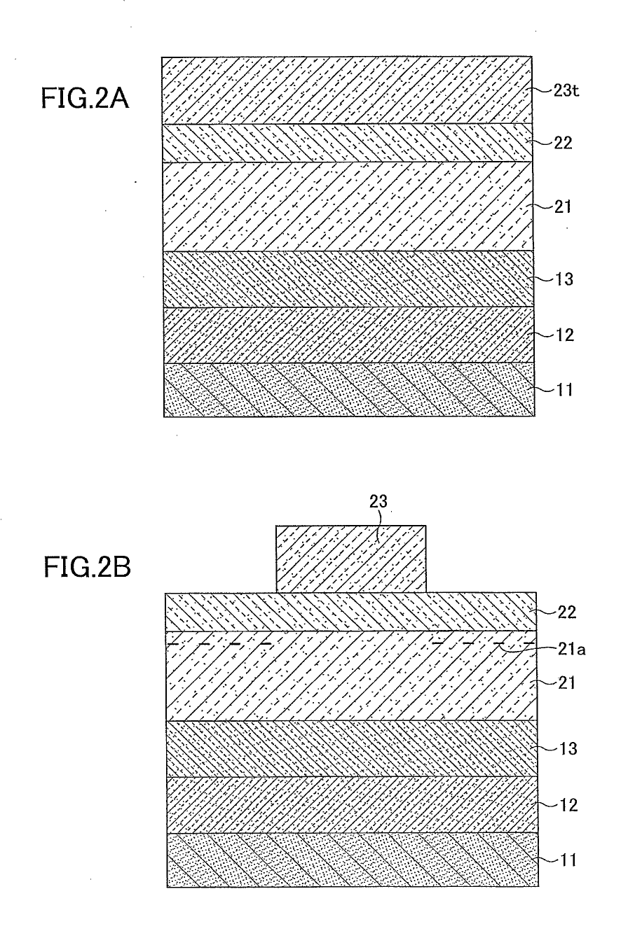

First, a nucleating agent 12, a buffer layer 13, an electron running layer 21, an electron supplying layer 22, and a p-GaN film 23t are sequentially laminated and formed on a substrate 11, due to epitaxial growth in accordance with an Metal-organic Vapor Phase Epitaxy (MOVPE) as illustrated in FIG. 2A.

Specifically, the nucleating layer 12 is formed by supplying trimethylaluminum (TMA) that is an organometallic material including Al and ammonia (NH₃) as raw material gasses and growing AlN to have a thickness of 200 nm on conditions that are a substrate temperature of 1000° C. and a growth pressure of 20 kPa.

The buffer layer 13 is formed by supplying trimethylgallium (TMG) that is an organometallic material including Ga, TMA, and NH₃, as raw material gasses and growing AlGaN to have a thickness of about 500 nm on conditions that are a substrate temperature of 1000° C. and a growth pressure of 40 kPa. Additionally, the buffer layer 13 in the present embodiment is formed of three layers with different composition ratios, wherein an Al_{0.8}Ga_{0.2}N layer, an Al_{0.5}Ga_{0.5}N layer, and an Al_{0.2}Ga_{0.8}N layer are formed in order from a side of the formed nucleating layer 12. It is possible to form the buffer layer 13 formed of such layers with different composition ratios by changing a ratio of amounts of supply of TMG and TMA.

The electron running layer 21 is formed by supplying TMG and NH₃ as raw material gasses and growing GaN to have a thickness of about 1000 nm on conditions that are a substrate temperature of 1000° C. and a growth pressure of 60 kPa.

The electron supplying layer 22 is formed by supplying TMG, TMA, and NH₃ as raw material gasses and growing Al_{0.2}Ga_{0.8}N to have a thickness of about 10 nm on conditions that are a substrate temperature of 1000° C. and a growth pressure of 40 kPa.

The p-GaN film 23t is formed by supplying TMG and NH₃ as raw material gasses and growing GaN to have a thickness of about 50 nm on conditions that are a substrate temperature of 1000° C. and a growth pressure of 60 kPa. Additionally, as the p-GaN film 23t is formed, cyclopentadienylmagnesium (CP2Mg) is supplied together with the raw material gasses so as to be doped with Mg that is an impurity element for attaining p-type. Herein, a concentration of doping Mg is about 4×10¹⁹ cm⁻³.

Then, the p-GaN layer 23 is formed in an area just under the gate electrode 31 as illustrated in FIG. 2B. Specifically, a photoresist is applied onto the p-GaN film 23t and light exposure and development are conducted by a light exposure device so that a not-illustrated resist pattern is formed in an area where the p-GaN layer 23 is to be formed. Subsequently, the p-GaN film 23t in an area where the resist pattern has not been formed is removed by dry etching such as a RIE so that the electron supplying layer 22 is exposed and thereby the p-GaN layer 23 is formed in an area where the gate electrode 31 is to be formed. Subsequently, the resist pattern is removed by an organic solvent or the like.

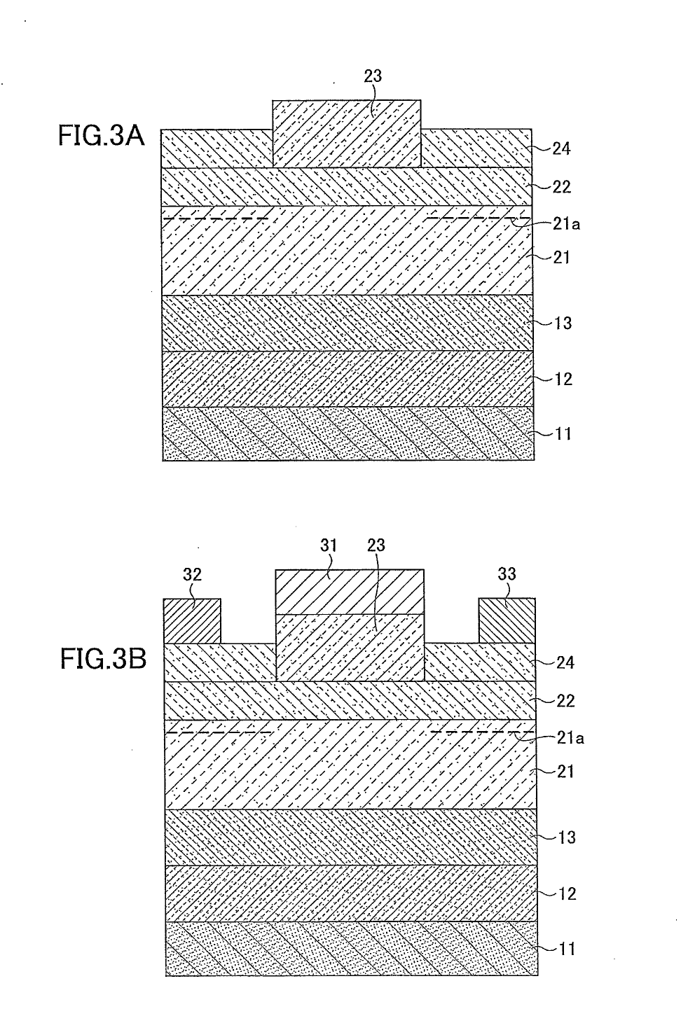

Then, the regrowth electron supplying layer 24 is formed on the electron supplying layer 22, by an MOVPE, as illustrated in FIG. 3A. The regrowth electron supplying layer 24 is formed by supplying TMG, TMA, and NH₃ as raw material gasses and growing Al_{0.2}Ga_{0.8}N to have a thickness of about 10 nm on conditions that are a substrate temperature of 920° C. and a growth pressure of 40 kPa. Additionally, as the regrowth electron supplying layer 24 is formed, silane (SiH₄) is supplied together with TMG, TMA, and NH₃ so as to be doped with Si. Herein, a concentration of doping Si is greater than or equal to 2×10¹⁷ cm⁻³ and less than or equal to 1×10¹⁹ cm⁻³. Furthermore, a composition ratio of Al in the electron supplying layer 22 and a composition ratio thereof in the regrowth electron supplying layer 24 are preferably identical from the viewpoint of crystallinity or the like, but may be different.

Furthermore, the regrowth electron supplying layer 24 in the present embodiment is formed at a temperature lower than a temperature for forming the electron supplying layer 22. This is because if a temperature at which the regrowth electron supplying layer 24 is formed is high, a defect is caused in the p-GaN layer 23 and thereby a normally-off state is not provided. Thus, it is preferable for the regrowth electron supplying layer 24 to be formed at a temperature at which damage is not provided to the p-GaN layer 23, that is, a temperature greater than or equal to 900° C. and less than 1000° C. Additionally, when an AlGaN layer is formed at a low temperature, a concentration of C included in the AlGaN layer is high, but it is possible to prevent an influence of a high concentration of C, because the regrowth electron supplying layer 24 in the present embodiment is doped with Si. That is, C functions as an acceptor in an AlGaN layer, but it is possible to cancel a function of C as an acceptor by being doped with Si that functions as a donor. Hence, formation is conducted in such a manner that a concentration of Si in the regrowth electron supplying layer 24 in the present embodiment is higher than a concentration of Si in the electron supplying layer 22.

Then, the gate electrode 31 is formed on the p-GaN layer 23, and a source electrode 32 and a drain electrode 33 are formed on the regrowth electron supplying layer 24, as illustrated in FIG. 3B. Thereby, it is possible to fabricate a semiconductor device in the present embodiment. Additionally, the gate electrode 31 is formed of a metal laminated film of Ni/Au and the source electrode 32 and the drain electrode 33 are formed of a metal laminated film of Ti/Al. As a semiconductor device in the present embodiment is manufactured, dry etching is not conducted for the electron supplying layer 22 just under the gate electrode 31, so that, in this area, the electron supplying layer 22 is not damaged by dry etching.

(Characteristics of a Semiconductor Device)

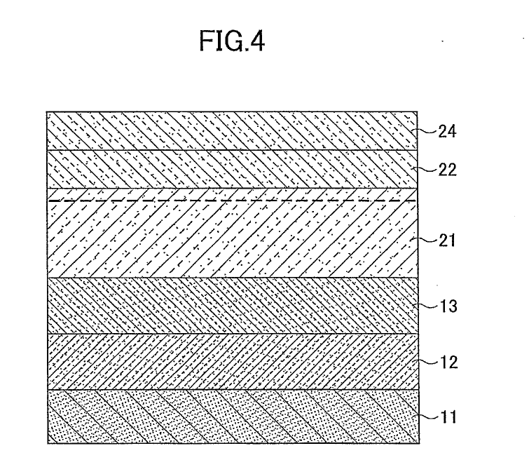

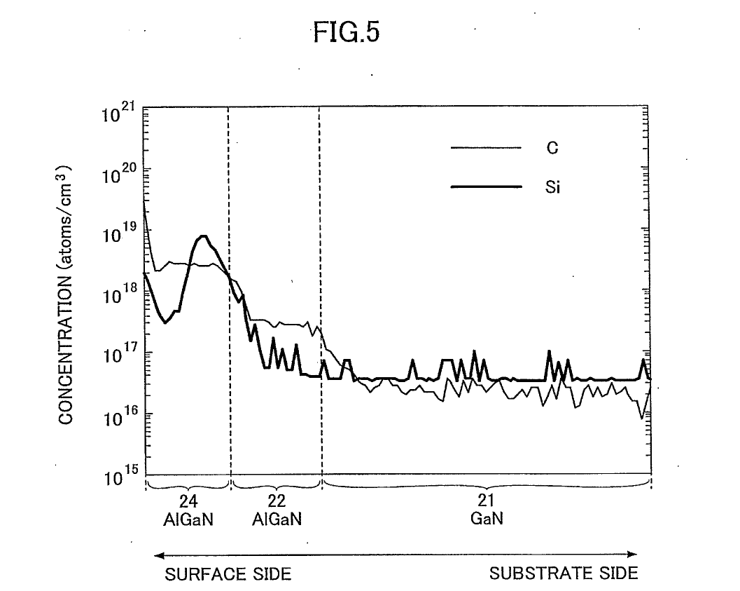

As a semiconductor device was fabricated by a method for manufacturing a semiconductor device in the present embodiment as described above, it was confirmed that a good normally-off characteristic was exhibited. Furthermore, after the p-GaN film 23t as illustrated in FIG. 2A was formed in the above-mentioned process, the p-GaN film 23t was all removed by dry etching, and subsequently, the regrowth electron supplying layer 24 was formed on the electron supplying layer 22 so that a sample with a structure illustrated in FIG. 4 was fabricated. As a sheet resistance of a thus fabricated sample was measured, the sheet resistance was 424 Ω/□. Additionally, this sample had a structure similar to a structure in an area where the gate electrode 31 was not formed, in an HEMT that was a semiconductor device in the present embodiment. FIG. 5 illustrates a result of measurement of a thus fabricated sample by Secondary Ion Mass Spectrometry (SIMS). Because the regrowth electron supplying layer 24 was formed at a temperature lower than that of the electron supplying layer 22, a concentration of C included in the regrowth electron supplying layer 24 was higher than a concentration of C included in the electron supplying layer 22, as illustrated in FIG. 5. Furthermore, whereas a concentration of Si in the electron supplying layer 22 was less than or equal to about 1×10¹⁷/cm³, a concentration of Si in the regrowth electron supplying layer 24 was on average greater than or equal to 1×10¹⁸/cm³ and Si more than that of the electron supplying layer 22 was included. Thus, the regrowth electron supplying layer 24 included C more than that of the electron supplying layer 22, but correspondingly, also included more Si that cancels a function of C as an acceptor. Hence, it was possible to obtain a value of a comparatively low sheet resistance without reducing 2DEG in the electron running layer 21.

Next, a case where an AlGaB layer corresponding to a regrowth electron supplying layer is formed at a substrate temperature of 1000° C. without being doped with Si and a case where an AlGaN layer corresponding to a regrowth electron supplying layer is formed at a substrate temperature of 920° C., differently from the present embodiment, will be described for comparison.

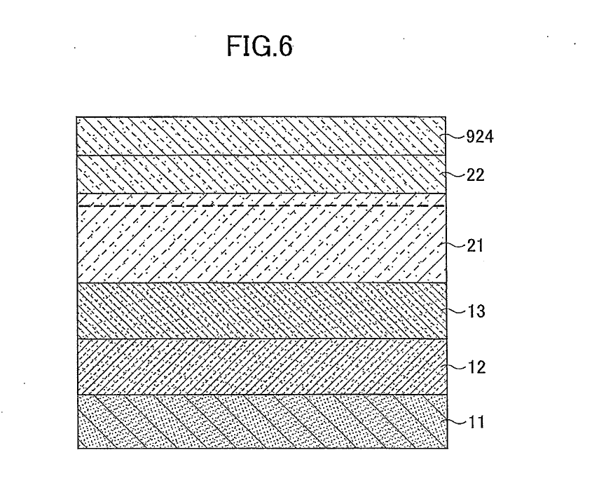

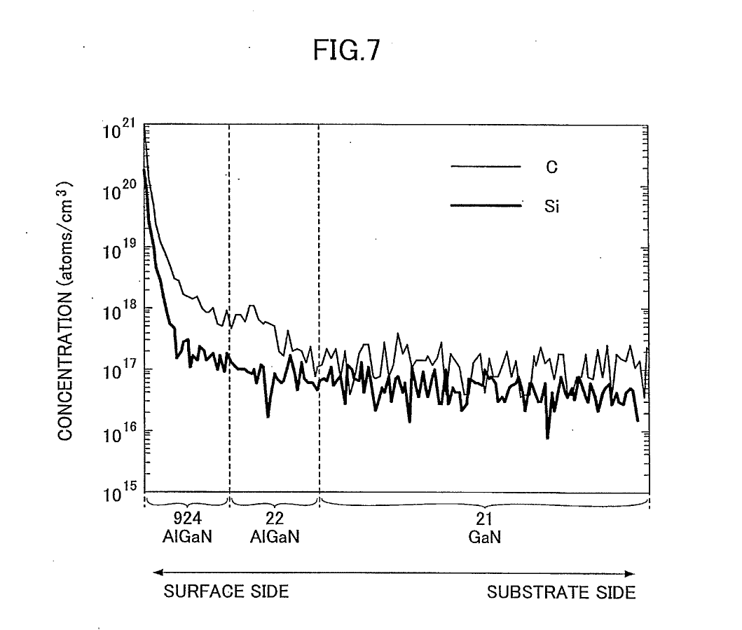

First, the case where an AlGaB layer corresponding to a regrowth electron supplying layer is formed at a substrate temperature of 1000° C. without being doped with Si will be described. A layer corresponding to a regrowth electron supplying layer to be formed in this case is formed by supplying TMG, TMA, and NH₃ as raw material gasses and growing an AlGaN layer to have a thickness of about 10 nm on conditions that are a substrate temperature of 1000° C. and a growth pressure of 40 kPa. A semiconductor device in which this layer corresponding to a regrowth electron supplying layer was formed did not exhibit a normally-off characteristic. It is considered that this is because a temperature was high for forming an AlGaN layer as a layer corresponding to a regrowth electron supplying layer, so that the p-GaN layer 23 was damaged and it was not possible to suppress generation of 2DEG just under a gate electrode. Furthermore, this layer corresponding to a regrowth electron supplying layer was used to fabricate a sample illustrated in FIG. 6 in a process similar to that described above. Specifically, after the p-GaN film 23t as illustrated in FIG. 2A was formed in the above-mentioned process, the p-GaN film 23t was all removed by dry etching and further a sample was fabricated in such a manner that a layer 924 corresponding to a regrowth electron supplying layer as described above was formed on the electron supplying layer 22. As a sheet resistance of a thus fabricated sample was measured, the sheet resistance was 456 Ω/□. FIG. 7 illustrates a result of measurement of a thus fabricated sample by SIMS. As illustrated in FIG. 7, the layer 924 corresponding to a regrowth electron supplying layer was formed at a temperature that was identical to that of the electron supplying layer 22, so that a concentration of C included in the layer 924 corresponding to a regrowth electron supplying layer was generally identical to a concentration of C included in the electron supplying layer 22. Furthermore, both a concentration of Si in the electron supplying layer 22 and a concentration of Si in the layer 924 corresponding to a regrowth electron supplying layer were generally 1×10¹⁷/cm³ and generally comparable. Thus, a concentration of C included in the layer 924 corresponding to a regrowth electron supplying layer was comparable with that of the electron supplying layer 22 and was a comparatively low concentration. Hence, it was possible to obtain a comparatively low sheet resistance without reducing 2DEG in the electron running layer 21 even though doping with Si was not conducted. Additionally, concentrations of Si and C being high at a side of a substrate in FIG. 7 were provided by an external influence.

Next, the case where an AlGaN layer corresponding to a regrowth electron supplying layer is formed at a substrate temperature of 920° C. without being doped with Si will be described. A layer corresponding to a regrowth electron supplying layer to be formed in this case is formed by supplying TMG, TMA, and NH₃ as raw material gasses and growing an AlGaN layer to have a thickness of about 10 nm on conditions that are a substrate temperature of 920° C. and a growth pressure of 40 kPa. It was confirmed that a semiconductor device in which this layer corresponding to a regrowth electron supplying layer was formed exhibited a good normally-off characteristic. It is considered that this is because a temperature was low for forming an AlGaN layer as a layer corresponding to a regrowth electron supplying layer, so that the p-GaN layer 23 was not damaged and elimination of 2DEG just under a gate electrode was maintained. Furthermore, this AlGaN layer was used to fabricate a sample similar to that illustrated in FIG. 4 or FIG. 6 in a process similar to that described above. Specifically, after the p-GaN film 23t as illustrated in FIG. 2A was also formed in the above-mentioned process, the p-GaN film 23t was all removed by dry etching and further a sample was fabricated in such a manner that a layer corresponding to a regrowth electron supplying layer was formed on the electron supplying layer 22. As a sheet resistance of a thus fabricated sample was measured, the sheet resistance was 628 Ω/□. It is considered that this is because a substrate temperature for forming an AlGaN layer was a low temperature of 920° C. so that more C was included in the formed AlGaN layer and Si for cancellation was also not present whereby 2DEG in the electron running layer was reduced.

Thus, it is possible for a semiconductor device in the present embodiment to attain a normally-off state and provide a low on-resistance.

### Second Embodiment

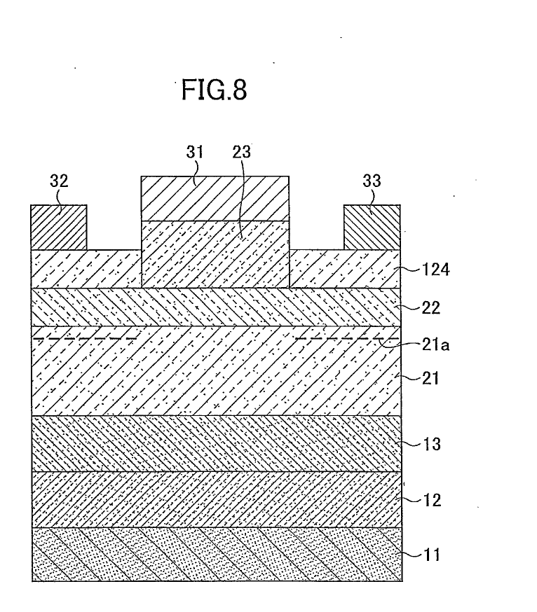

Next, a second embodiment will be described. The present embodiment is for a semiconductor device with a regrowth electron supplying layer being formed of an InAlN. Specifically, a regrowth electron supplying layer 124 is formed of an InAlN on an electron supplying layer 22 as illustrated in FIG. 8. A concentration of Si doping this regrowth electron supplying layer 124 is higher than a concentration of Si in the electron supplying layer 22. For example, whereas a concentration of Si in the electron supplying layer 22 is less than or equal to about 1×10¹⁷/cm³, a concentration of Si in the regrowth electron supplying layer 124 is on average greater than or equal to 1×10¹⁸/cm³, and Si more than that of the electron supplying layer 22 is included.

In a method for manufacturing a semiconductor device in the present embodiment, a substrate temperature for forming the regrowth electron supplying layer 124 is 700° C. and formation thereof is conducted by MOVPE while trimethylindium (TMI), TMA, and NH₃ are raw material gasses. Thus, the regrowth electron supplying layer 124 is formed of an In_{0.17}Al_{0.38}N layer with a thickness of about 10 nm. Additionally, when the regrowth electron supplying layer 124 is formed, silane (SiH₄) is supplied together with the raw material gasses to be doped with Si. Herein, a concentration of doping Si is greater than or equal to 2×10¹⁷ cm⁻³ and less than or equal to 1×10¹⁹ cm⁻³. Additionally, a content(s) other than as described above is/are similar to that/those in the first embodiment.

### Third Embodiment

Next, a third embodiment will be described. The present embodiment is for a semiconductor device, a power supply device, and a high-frequency amplifier.

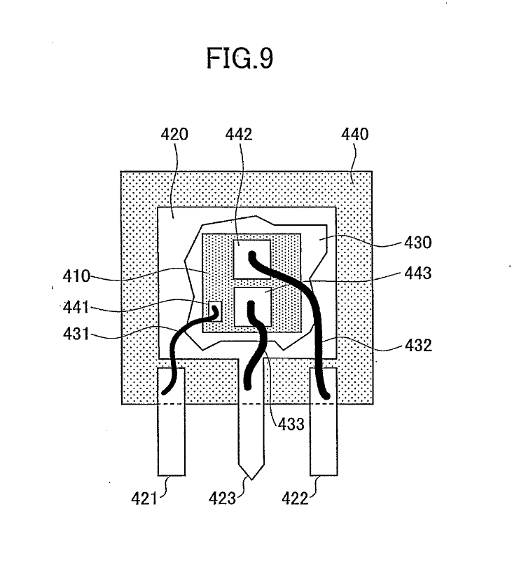

A semiconductor device in the present embodiment is such that a semiconductor device in the first or second embodiment is discretely packaged, wherein a thus discretely packaged semiconductor device will be described based on FIG. 9. Additionally, FIG. 9 schematically illustrates an inside of the discretely packaged semiconductor device, wherein arrangement of electrodes or the like is different from that illustrated in the first or second embodiment.

First, a semiconductor device manufactured in the first or second embodiment is cut by dicing or the like to form a semiconductor chip 410 that is an HEMT of a GaN-type semiconductor material. This semiconductor chip 410 is fixed on a lead frame 420 by a die-attaching agent 430 such as a solder.

Then, a gate electrode 441 is connected to a gate lead 421 by a bonding wire 431, while a source electrode 442 is connected to a source lead 422 by a bonding wire 432 and a drain electrode 443 is connected to a drain lead 423 by a bonding wire 433. Additionally, the bonding wires 431, 432, and 433 are formed of a metal material such as Al. Furthermore, the gate electrode 441 in the present embodiment is a gate electrode pad that is connected to the gate electrode 31 in the first or second embodiment. Similarly, the source electrode 442 is a source electrode pad that is connected to the source electrode 32 and the drain electrode 443 is a drain electrode pad that is connected to the drain electrode 33.

Then, plastic sealing with a molded resin 440 is conducted by a transfer molding method. Thus, it is possible to fabricate a discretely packaged semiconductor device that is an HEMT using a GaN-type semiconductor material.

Furthermore, a power supply device and a high-frequency amplifier in the present embodiment are a power supply device and a high-frequency amplifier using the semiconductor device in the first or second embodiment, respectively.

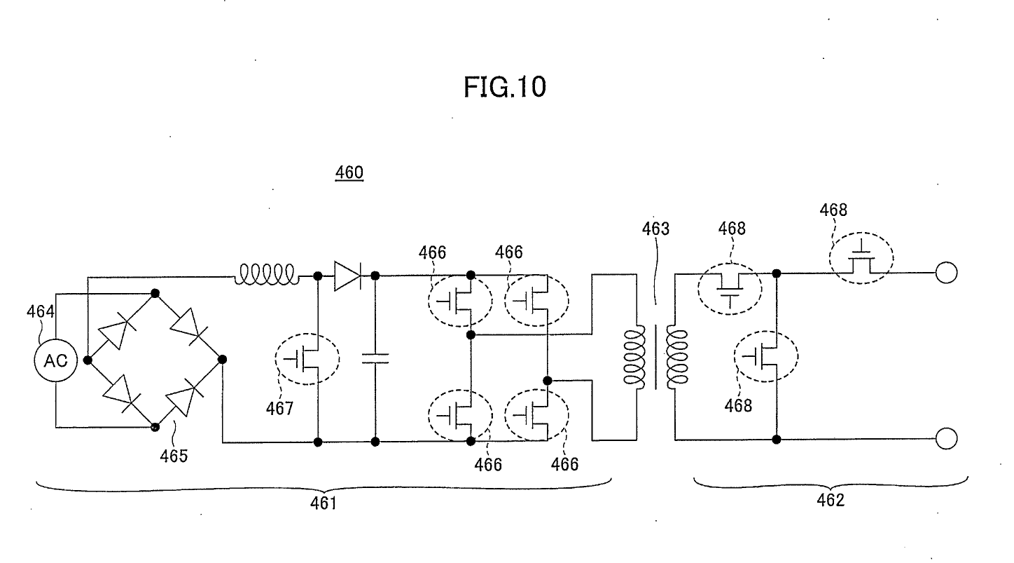

A power supply device in the present embodiment will be described based on FIG. 10. A power supply device 460 in the present embodiment includes a primary circuit 461 at a high voltage, a secondary circuit 462 at a low voltage, and a transformer 463 arranged between the primary circuit 461 and the second circuit 462. The primary circuit 461 includes an alternating current power supply 464, a so-called bridge rectifier circuit 465, a plurality of (four, in an example illustrated in FIG. 10) switching elements 466, one switching element 467, and the like. The secondary circuit 462 includes a plurality of (three, in an example illustrated in FIG. 10) switching elements 468. In an example illustrated in FIG. 10, semiconductor devices in the first or second embodiment are used as switching elements 466 and 467 of the primary circuit 461. Additionally, it is preferable for the switching elements 466 and 467 of the primary circuit 461 to be normally-off type semiconductor devices. Furthermore, a normal metal insulator semiconductor field effect transistor (MISFET) formed of silicon is used for the switching elements 468 used in the secondary circuit 462.

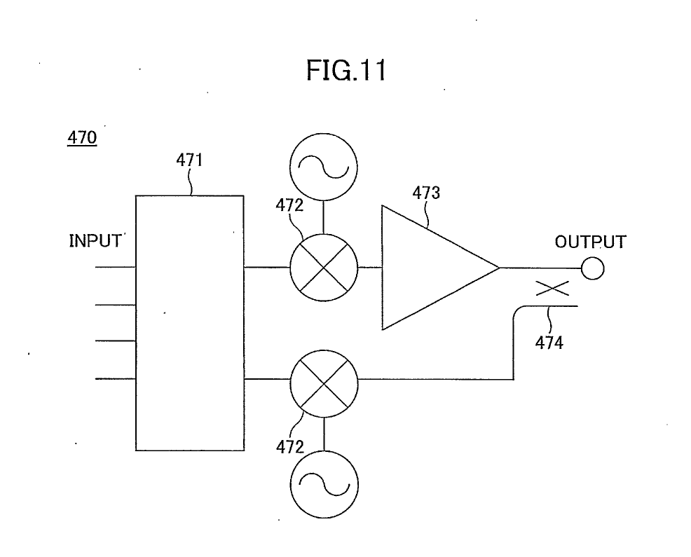

Next, a high-frequency amplifier in the present embodiment will be described based on FIG. 11. A high-frequency amplifier 470 in the present embodiment may be applied to, for example, a power amplifier for a base station of a mobile phone. This high-frequency amplifier 470 includes a digital pre-distortion circuit 471, mixers 472, a power amplifier 473, and a directional coupler 474. The digital pre-distortion circuit 471 compensates for nonlinear distortion of an input signal. The mixer 472 mixes an input signal compensated for nonlinear distortion with an alternating current signal. The power amplifier 473 amplifies the input signal mixed with the alternating current signal. In an example illustrated in FIG. 11, the power amplifier 473 has a semiconductor device in the first or second embodiment. The directional coupler 474 conducts monitoring of an input signal or an output signal, or the like. In a circuit illustrated in FIG. 11, for example, it is possible for the mixer 472 to mix an output signal with an alternating current signal to be transmitted to the digital pre-distortion circuit 471, due to switching of a switch.

According to a semiconductor device and a method for manufacturing a semiconductor device as disclosed in the above-mentioned embodiments, it is possible to obtain a normally-off type semiconductor device with a low on-resistance.

All examples and conditional language provided herein are intended for the pedagogical purposes of aiding the reader in understanding the invention and the concepts contributed by the inventor to further the art, and are not to be construed as limitations to such specially recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor device, comprising:
a first semiconductor layer formed on a substrate;
a second semiconductor layer formed on the first semiconductor layer;
a third semiconductor layer and a fourth semiconductor layer formed on the second semiconductor layer;
a gate electrode formed on the third semiconductor layer; and
a source electrode and a drain electrode contacting and formed on the fourth semiconductor layer,
wherein the third semiconductor layer is formed of a semiconductor material for attaining p-type on an area just under the gate electrode, and a concentration of silicon in the fourth semiconductor layer is higher than that in the second semiconductor layer.

2. The semiconductor device as claimed in claim 1, wherein the fourth semiconductor layer is doped with silicon at a concentration greater than or equal to 2×10¹⁷ cm⁻³ and less than or equal to 1×10¹⁹ cm⁻³.

3. The semiconductor device as claimed in claim 1, wherein the first semiconductor layer is formed of a material including GaN.

4. The semiconductor device as claimed in claim 1, wherein the third semiconductor layer is of a material including GaN and doped with an impurity element for attaining p-type.

5. The semiconductor device as claimed in claim 4, wherein the impurity element for attaining p-type film is Mg.

6. The semiconductor device as claimed in claim 1, wherein the second semiconductor layer is formed of a material including AlGaN.

7. The semiconductor device as claimed in claim 1, wherein the fourth semiconductor layer is formed of a material including AlGaN or a material including InAlN or any combination thereof.

8. The semiconductor device as claimed in claim 6, wherein the fourth semiconductor layer is formed of a material including AlGaN and a composition ratio of Al in the second semiconductor layer is generally equal to a composition ratio of Al in the fourth semiconductor layer.

9. The semiconductor device as claimed in claim 1, wherein the substrate is a silicon substrate.

10. The semiconductor device as claimed in claim 1, wherein a buffer layer is formed of a material including AlGaN between the substrate and the first semiconductor layer.

11. A power supply device comprising the semiconductor device as claimed in claim 1.

12. An amplifier comprising the semiconductor device as claimed in claim 1.

13. A method for manufacturing a semiconductor device, comprising:
laminating and forming a first semiconductor layer, a second semiconductor layer, and a third semiconductor layer on a substrate sequentially;
removing the third semiconductor layer in an area except an area for forming a gate electrode on the third semiconductor layer;
forming a fourth semiconductor layer on the second semiconductor layer with the third semiconductor layer being removed;
forming the gate electrode on the third semiconductor layer; and
forming a source electrode and a drain electrode to contact the fourth semiconductor layer,
wherein the third semiconductor layer is formed of a semiconductor material doped with an impurity element for attaining p-type and the fourth semiconductor layer is doped with silicon as an impurity element at time of forming thereof.

14. The method for manufacturing a semiconductor device as claimed in claim 13, wherein a concentration of silicon in the fourth semiconductor layer is higher than that in the second semiconductor layer.

15. The method for manufacturing a semiconductor device as claimed in claim 13, wherein the first semiconductor layer, the second semiconductor layer, the third semiconductor layer, and the fourth semiconductor layer are formed by an MOVPE.

16. The method for manufacturing a semiconductor device as claimed in claim 13, wherein a temperature of the substrate to form the fourth semiconductor layer is lower than a temperature of the substrate to form the second semiconductor layer.

17. The method for manufacturing a semiconductor device as claimed in claim 13, wherein the second semiconductor layer is formed of a material including AlGaN.

18. The method for manufacturing a semiconductor device as claimed in claim 13, wherein the fourth semiconductor layer is formed of material including AlGaN or a material including InAlN or any combination thereof.

19. The method for manufacturing a semiconductor device as claimed in claim 13, wherein silane is supplied to form the fourth semiconductor layer.

20. The method for manufacturing a semiconductor device as claimed in claim 13, wherein the first semiconductor layer is formed of a material including GaN.
